(19) United States
(12) Patent Application Publication
(10) Pub. No.: US 2024/0391209 A1
(43) Pub. Date: Nov. 28, 2024

(54) BUFFER STRUCTURE AND PREPARATION METHOD FOR SAME, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventor: Kailong ZUO, Beijing (CN)

(21) Appl. No.: 18/701,587

(22) PCT Filed: Apr. 21, 2023
(86) PCT No.: PCT/CN2023/089686

§ 371 Date: Apr. 15, 2024

(30) Foreign Application Priority Data
Jun. 24, 2022 (CN) 202210730292.9

(51) Int. Cl. B32B 5/18; B29C 48/00; B29C 48/08; B29C 48/29; B29K 105/16; B29K 505/10; B29K 507/04; B29K 509/04; B29L 31/34; B32B 15/04; B32B 15/20; H10K 77/10; H10K 102/00

(52) U.S. Cl. CPC B32B 5/18; B32B 15/046; B32B 15/20; H10K 77/111; B29C 48/0012; B29C 48/023; B29C 48/08; B29C 48/29; B29K 2105/16; B29K 2505/10; B29K 2507/04; B29K 2509/04; B29K 2995/0005; B29K 2995/0013; B29L 2031/3475; B32B 2264/1055; B32B 2266/0214; B32B 2266/104; B32B 2307/202; B32B 2307/302; B32B 2307/7376; B32B 2457/20; H10K 2102/311

(57) ABSTRACT

A buffer structure, a preparation method for the buffer structure, and a display apparatus are provided. The buffer structure includes a substrate layer. A plurality of microporous structures are distributed in the substrate layer. The substrate layer is doped with electrically and thermally conductive materials. The electrically and thermally conductive material is distributed in the whole-layer structure of the substrate layer. The electrically and thermally conductive materials forms a heat conducting network structure in the substrate layer.

### CROSS-REFERENCE TO RELATED APPLICATIONS

The present disclosure is a National Stage of International Application No. PCT/CN2023/089686 filed Apr. 21, 2023, which claims priority to the Chinese Patent Application No. 202210730292.9, filed with the China National Intellectual Property Administration (CNIPA) on Jun. 24, 2022, and entitled “Buffer Structure and Preparation Method for Same, and Display Apparatus”, the entire contents of which are incorporated herein by reference.

### TECHNICAL FIELD

The present disclosure relates to the technical field of display, in particular to a buffer structure and a preparation method for the buffer structure, and a display apparatus.

### BACKGROUND

An organic light-emitting diode, abbreviated as OLED, has the advantages of self-illumination, small thickness and weight, low energy consumption, high reaction rate, bright colors, good flexibility, low operating voltage and a simple production process, and has become a very important display technology today. At present, a super clean foam (SCF) layer used under a backplane in an OLED display apparatus adopts a multilayer structure, as shown in FIG. 1, which is usually composed of three layers of foam, graphite and copper foil. Foam plays a role in the performance of impact resistance, but its heat conductivity is poor, which adversely affects a heat conductivity of the SCF layer. Therefore, how to improve the heat conductivity of the SCF layer is a project that needs to be researched urgently.

### SUMMARY

A buffer structure includes a substrate layer.

A plurality of microporous structures are distributed in the substrate layer. The substrate layer is doped with an electrically and thermally conductive material. The electrically and thermally conductive material is distributed in a whole-layer structure of the substrate layer. The electrically and thermally conductive material forms a heat conduction network structure in the substrate layer.

In some embodiments, the electrically and thermally conductive material includes at least one of carbon fiber, carbon nanotubes, graphene, and titanium carbide.

In some embodiments, the substrate layer includes a high polymer material.

In some embodiments, the high polymer material includes at least one of polypropylene, polyethylene terephthalate, thermoplastic polyurethane, polyvinylidene fluoride, and polylactic acid.

In some embodiments, a weight ratio of the high polymer material to the electrically and thermally conductive material is (90-95):(5-10).

In some embodiments, the substrate layer is further doped with copper powder.

In some embodiments, a weight ratio of the high polymer material to the copper powder to the electrically and thermally conductive material is (85-90):(5-3):(10-7).

In some embodiments, a diameter of the microporous structure is larger than or equal to 1 μm and is smaller than or equal to 10 μm.

In some embodiments, a layer thickness of the substrate layer is larger than or equal to 0.1 mm and is smaller than or equal to 0.5 mm.

In some embodiments, a copper foil is arranged on a surface of the substrate layer.

In some embodiments, reticulated tape is arranged on outmost sides of two sides of the buffer structure respectively.

Based on the same inventive concept, the present disclosure further provides a display apparatus, including a display panel and any one buffer structure provided by the above technical solution. The buffer structure is located on a back side of the display panel.

Based on the same inventive concept, the present disclosure further provides a preparation method for a buffer structure, including:
mixing a high polymer material and an electrically and thermally conductive material evenly to form a composite material;
loading the composite material into an extruder for melt blending, and inletting a supercritical fluid; and
forming the buffer structure by extruding, foaming, molding by the extruder.

Based on the same inventive concept, the present disclosure further provides a preparation method for a buffer structure, including:
dissolving a high polymer material by using a dissolving solution;
adding an electrically and thermally conductive material into a high polymer material solution after dissolution, and causing the electrically and thermally conductive material to be evenly distributed in the high polymer material solution;
obtaining a composite material by subjecting the high polymer material solution doped with the electrically and thermally conductive material to drying treatment; and
obtaining the buffer structure by causing microporous structures to be formed in the composite material through an intermittent foaming method.

### BRIEF DESCRIPTION OF FIGURES

FIG. 1 is a stereo schematic structural diagram of a buffer structure provided by an embodiment of the present disclosure.

FIG. 2 is a sectional schematic structural diagram of a buffer structure provided by an embodiment of the present disclosure.

FIG. 3 is a sectional schematic structural diagram of a buffer structure provided by an embodiment of the present disclosure.

FIG. 4 is a sectional schematic structural diagram of a buffer structure provided by an embodiment of the present disclosure.

FIG. 5 is a schematic diagram of heat conduction in a buffer structure provided by an embodiment of the present disclosure.

FIG. 6 is a schematic diagram of electromagnetic wave conduction of a buffer structure provided by an embodiment of the present disclosure.

FIG. 7 is a local sectional schematic structural diagram of a display apparatus provided by an embodiment of the present disclosure.

FIG. 8 is a schematic flow chart of a preparation method for a buffer structure provided by an embodiment of the present disclosure.

FIG. 9 is a schematic flow chart of a preparation method for a buffer structure provided by an embodiment of the present disclosure.

### DETAILED DESCRIPTION

Technical solutions in the embodiments of the present disclosure will be clearly and completely described below in conjunction with the accompanying drawings in the embodiments of the present disclosure. Obviously, the embodiments described are only a part of the embodiments of the present disclosure, and not all of the embodiments. Based on the embodiments in the present disclosure, all other embodiments obtained by those of ordinary skill in the art without making creative labor fall within the scope of protection of the present disclosure.

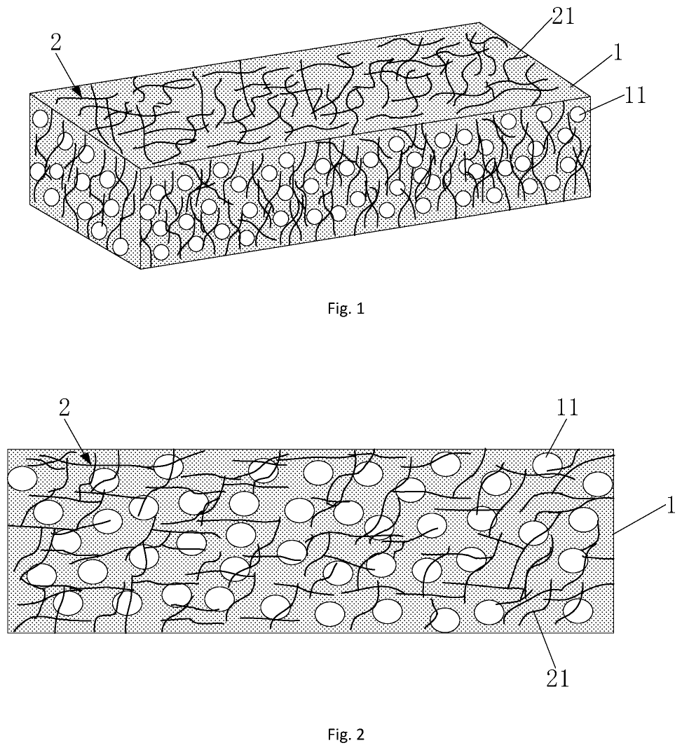

As shown in FIG. 1 and FIG. 2, embodiments of the present disclosure provide a buffer structure. The buffer structure includes a substrate layer 1. A plurality of microporous structures 11 are distributed in the substrate layer 1. The substrate layer 1 is doped with electrically and thermally conductive material 21. The electrically and thermally conductive material 21 is distributed in a whole-layer structure of the substrate layer 1, and the electrically and thermally conductive material 21 forms a heat conduction network structure 2 in the substrate layer 1.

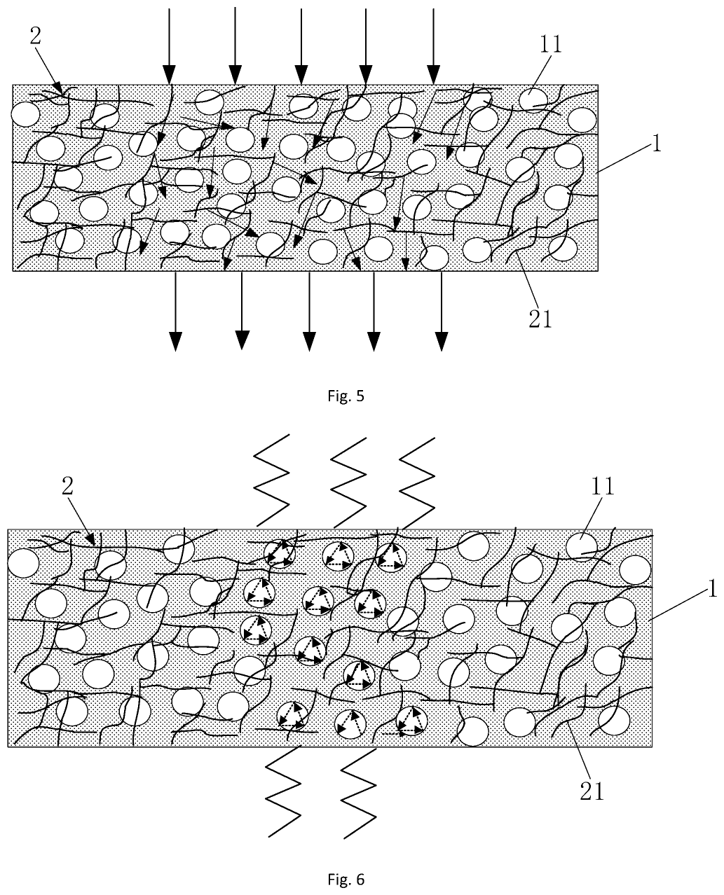

In the above buffer structure, as shown in FIG. 2, the plurality of microporous structures 11 are provided in the substrate layer 1, and the microporous structures 11 are distributed in the whole-layer structure of the substrate layer 1, so that the substrate layer 1 has a high porosity, an impact resisting capacity of the substrate layer 1 is improved, the substrate layer 1 has a good impact resistance, a weight of the buffer structure may be reduced, and the design needs of a thin and light display apparatus are satisfied. In some embodiments, the microporous structures 11 may be evenly distributed in the substrate layer 1, so that the substrate layer 1 has a better overall impact resistance performance and may achieve a good buffering effect. Meanwhile, as shown in FIG. 1 and FIG. 5, an arrow in the substrate layer in FIG. 5 represents heat conduction, and only a local part is shown. The substrate layer 1 is further doped with the electrically and thermally conductive material 21, and the electrically and thermally conductive material 21 is distributed in the whole-layer structure of the substrate layer 1. In some embodiments, the electrically and thermally conductive material 21 may be evenly distributed in the whole-layer structure. Adjacent electrically and thermally conductive materials 21 are connected with each other. A connection relationship among the electrically and thermally conductive materials 21 connected with one another extends towards a periphery. The electrically and thermally conductive materials 21 in the substrate layer 1 are connected with one another and extended, and therefore a network structure is formed in the substrate layer 1. The electrically and thermally conductive material 21 is also distributed on a surface of the substrate layer 1, forming a part of the network structure, so that the network structure penetrates through an inside and an outside of the substrate layer 1. That is, a part of the network structure is exposed on the surface of the substrate layer 1. Because the electrically and thermally conductive material 21 is distributed in the whole-layer structure of the substrate layer 1, preferably, all the electrically and thermally conductive materials 21 may form an integral network structure, or may form at least two network structures without a connection relation between each other, the network structure may perform heat conduction to form a heat conduction network structure 2. The heat conduction network structure 2 may perform heat conduction well, heat may be conducted along the network structure, and the heat is conducted to the surface of the buffer structure to be dissipated. Meanwhile, because the network structure extends in the whole-layer structure in the substrate layer 1, heat stored in the microporous structures 11 may be timely conducted and dissipated, which greatly improves a heat dissipation capacity of the buffer structure, so that the buffer structure has a good heat dissipation performance. Furthermore, as shown in FIG. 6, a dotted arrow in the microporous structures in FIG. 6 represents consumption of electromagnetic waves. Each microporous structure has a function of consuming the electromagnetic waves, although electromagnetic wave consumption in merely a part of the microporous structures is illustrated in the drawing. Because of the existence of the microporous structures 11, after the electromagnetic waves enter the buffer structure, a part of the electromagnetic waves are repeatedly reflected in the microporous structures 11, so the electromagnetic waves are dissipated in the microporous structures 11. In addition, the electrically and thermally conductive material 21 in the substrate layer 1 has excellent electrical conductivity, and the entire heat conduction network structure 2 may also absorb and consume the electromagnetic waves, so the ability of absorbing the electromagnetic waves of the entire buffer structure may be further improved, a shielding capacity of the buffer structure is thus improved, the buffer structure has a good shielding performance, and interference between signals is reduced, which is conducive to improving a display performance and prolonging a service life of a display panel 6.

The above buffer structure has good buffering, heat dissipation and electromagnetic shielding performances, and integrates multiple functions. The single-layer buffer structure may be arranged on a back side of a display panel, may conduct heat generated by a screen at a high efficiency so as to improve a heat dissipation performance of the screen, and may fulfil functions of buffering and absorbing electromagnetic waves. The single-layer buffer structure may replace an existing multi-layer functional structural layer, which is conducive to reducing an overall thickness of the screen. In addition, for an SCF layer of a multi-layer structure in the related art, cohesiveness between sections of adjacent layers needs to be further treated, and a preparation process is complicated, while the buffer structure in the embodiments is of a single-layer structure, and may be prepared by doping a material of the substrate layer with the electrically and thermally conductive material and mixing the two. The preparation process is simple, and the production cost of a display apparatus is reduced.

In some embodiments, the electrically and thermally conductive material may adopt a highly electrically and thermally conductive material which has a good electrical and heat conductivity. In some embodiments, the electrically and thermally conductive material may adopt at least one of carbon fiber, carbon nanotubes, graphene, and titanium carbide, or may adopt one or a combination of several of carbon fiber, carbon nanotubes, graphene, and titanium carbide. Carbon fiber, carbon nanotubes, graphene, and titanium carbide all have an excellent electrical and heat conductivity, so through selection of one or more of carbon fiber, carbon nanotubes, graphene, and titanium carbide, the heat conductivity, electrical conduction performance, heat dissipation capacity and shielding capacity of the buffer structure may be further improved. In addition, by doping the substrate layer with one or more of carbon fiber, carbon nanotubes, graphene, and titanium carbide, the buffer structure is made black, and therefore the buffer structure has a light shielding function, so that the buffer structure has a good light shielding effect on a back side of a screen.

In some embodiments, based on the above buffer structure, for selection of material of the substrate layer, the substrate layer may be arranged to include a high polymer material. The high polymer material is mixed with the above electrically and thermally conductive material to form a composite foaming material, which then forms the buffer structure. The composite foaming material is small in density and mass, a weight of the screen may be effectively lowered, and a thin and light design of the screen may be satisfied.

In some embodiments, the high polymer material may include at least one of polypropylene, polyethylene terephthalate, thermoplastic polyurethane, polyvinylidene fluoride, and polylactic acid. The high polymer material may adopt one or more of polypropylene, polyethylene terephthalate, thermoplastic polyurethane, polyvinylidene fluoride, and polylactic acid, so the substrate layer has a better flexibility and impact resistance, the flexibility and impact resistance of the buffer structure may be improved, and a protection performance on the screen is improved. In addition, one or a mixture of several of polypropylene, polyethylene terephthalate, thermoplastic polyurethane, polyvinylidene fluoride, and polylactic acid are mixed with the above electrically and thermally conductive material to form the composite material, and the buffer structure may be formed through a simple preparation process, which is conducive to simplifying the preparation process.

In some embodiments, a weight ratio of the high polymer material to the electrically and thermally conductive material is set to be (90-95):(5-10). Mixing the high polymer material and the electrically and thermally conductive material at an appropriate weight ratio is conducive to forming a suitable number of microporous structures in the substrate layer, and the substrate layer has a high porosity and better impact resistance capacity. Meanwhile, the electrically and thermally conductive material may be reasonably distributed in the substrate layer to form the heat conduction network structure, so as to improve the heat conductivity and shielding capacity. In some embodiments, the weight ratio of the high polymer material to the electrically and thermally conductive material may be set to be 90:10, or that of the high polymer material to the electrically and thermally conductive material may be set to be 94:7, or other ratios may be set, which is not limited in the embodiments.

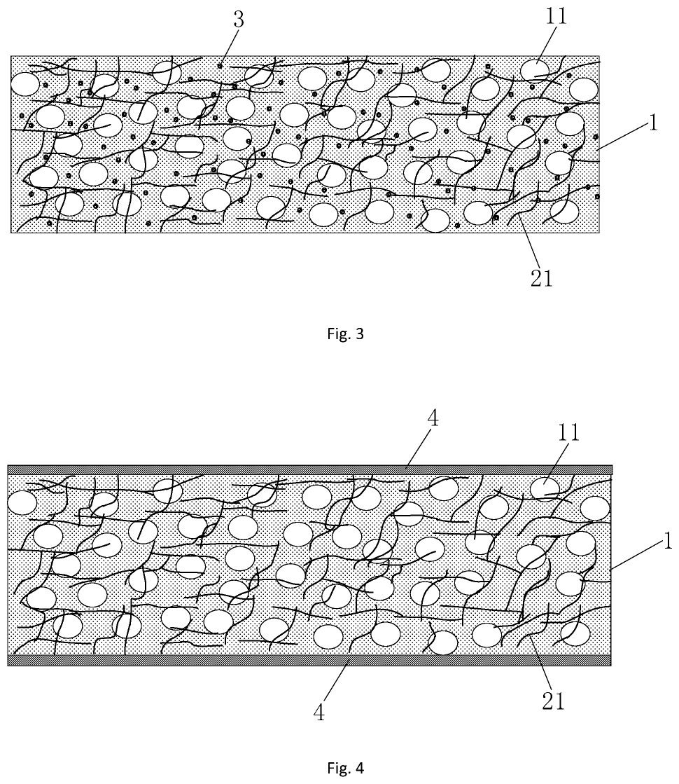

In one possible implementation, as shown in FIG. 3, the substrate layer 1 may be further doped with copper powder 3. The copper powder 3 may be distributed in the whole-layer structure of the substrate layer 1. The copper powder 3 may further improve a heat conduction efficiency and shielding performance of the buffer structure, so that the buffer structure has better heat dissipation and shielding performances.

In some embodiments, a weight ratio of the high polymer material to the copper powder to the electrically and thermally conductive material is (85-90):(5-3):(10-7). Mixing the high polymer material, the copper powder and the electrically and thermally conductive material at an appropriate weight ratio is conducive to forming a suitable number of microporous structures in the substrate layer, and the substrate layer has a high porosity and better impact resistance capacity. Meanwhile, the copper powder and the electrically and thermally conductive material may be reasonably distributed in the substrate layer, so as to improve the heat dissipation capacity and shielding capacity of the buffer structure.

In one possible implementation, as shown in FIG. 2, a diameter of the microporous structure 11 is larger than or equal to 1 μm and is smaller than or equal to 10 μm. Setting an appropriate diameter for the microporous structures 11 may improve the impact resisting capacity of the substrate layer 1, and influence on its heat dissipation performance is reduced as much as possible. In addition, the plurality of microporous structures in the substrate layer may have the same diameter or different diameters, which is not limited in the embodiments.

In one possible implementation, as shown in FIG. 2, a layer thickness of the substrate layer 1 is larger than or equal to 0.1 mm and is smaller than or equal to 0.5 mm. In some embodiments, the thickness of the substrate layer 1 may be set to be 0.2 mm, 0.25 mm, 0.3 mm, 0.32 mm, 0.35 mm, 0.37 mm, 0.4 mm, or other, which is not limited in the embodiments. By setting an appropriate thickness for the substrate layer 1, its impact resistance may be guaranteed, and good heat dissipation may also be guaranteed.

In the above buffer structure, as shown in FIG. 4, a copper foil 4 is arranged on a surface(s) of the substrate layer 1. The copper foil 4 is attached to the surface of the substrate layer 1, so that the overall heat dissipation and shielding performances may be greatly improved. In some embodiments, copper foils 4 may be arranged on an upper surface and a lower surface, opposite to the screen, of the substrate layer 1, or the copper foils 4 may be arranged on all surfaces of the substrate layer 1. The copper foils 4 wrap the surfaces of the substrate layer 1, so that the buffer structure has better overall heat dissipation and shielding performances.

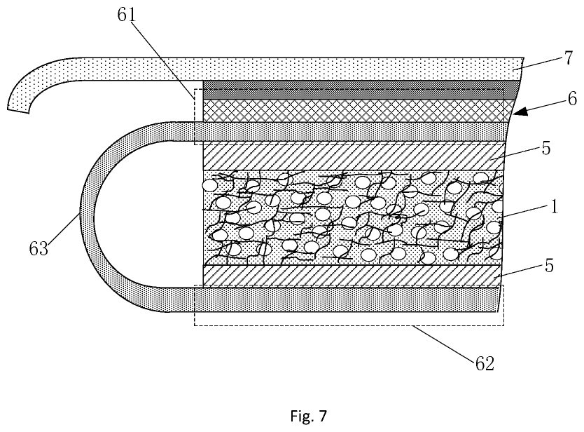

Further, as shown in FIG. 7, reticulated tape 5 is further arranged on outmost sides of two sides of the buffer structure respectively. The buffer structure is bonded to the display panel through the reticulated tape. A connection is simple and firm, and stability of the buffer structure on the back side of the display panel is improved.

Based on the arrangement of the above buffer structure, as shown in FIG. 2, as an example of a specific implementation of the buffer structure, the buffer structure may adopt polyethylene glycol terephthalate as the material of the substrate layer 1, and adopt carbon fiber as the electrically and thermally conductive material 21. That is, the buffer structure is formed by a composite material formed by mixing the polyethylene glycol terephthalate and the carbon fiber, and the microporous structures 11 are formed in the substrate layer 1. The carbon fiber has good electrical and heat conduction performance. The carbon fiber is dispersed in the substrate layer 1, and a good carbon fiber network may be formed. The carbon fiber is low in cost and resistant to high temperature. In a preparation process, the mixture of the polyethylene glycol terephthalate and the carbon fiber may be loaded in an extruder for direct preparation. The preparation process is simple and reliable, and the preparation cost of the buffer structure is greatly lowered.

As an example of another specific implementation of the buffer structure, as shown in FIG. 3, the buffer structure may further adopt polyvinylidene fluoride as the material of the substrate layer 1, and adopt carbon fiber as the electrically and thermally conductive material 21. The substrate layer 1 is doped with the copper powder 3. The buffer structure is formed by a composite material formed by mixing the polyvinylidene fluoride, the carbon fiber and the copper powder 3, and the microporous structures 11 are formed in the substrate layer 1 in the preparation process. Through the addition of the copper powder 3, the shielding effect may be further enhanced. The carbon fiber and the copper powder 3 are low in cost and are resistant to high temperature. In a preparation process, the mixture of the polyvinylidene fluoride, the carbon fiber and the copper powder 3 may be loaded in an extruder for direct preparation. The preparation process is simple and reliable, and the preparation cost of the buffer structure is greatly lowered.

As shown in FIG. 4, as an example of another specific implementation of the buffer structure, the buffer structure may further adopt thermoplastic polyurethane as the material of the substrate layer 1, and adopt carbon fiber as the electrically and thermally conductive material 21. A mixture formed by mixing the thermoplastic polyurethane and the carbon fiber are used as the composite material. The substrate layer 1 doped with the carbon fiber is formed by the composite material through an extruder. The microporous structures 11 are formed in the substrate layer 1 in the preparation process. A layer of copper foil 4 is attached to each of the two surfaces, opposite to the display panel 6, of the substrate layer 1, thus to form the final buffer structure. The copper foil 4 may further improve the heat dissipation and shielding performances of the buffer structure, the material of the copper foil is low in cost, and the preparation cost of the buffer structure is greatly lowered.

Based on the same inventive concept, Embodiments further provide a display apparatus. As shown in FIG. 7, the display apparatus includes a display panel 6 and any one buffer structure provided by the above embodiments. The buffer structure is located on a back side of the display panel 6. The display panel 6 has a substrate, and an organic light-emitting functional layer and a polarizer which are arranged on the substrate. The buffer structure is located on a side of the substrate facing away from the organic light-emitting functional layer, and the polarizer is located on a side of the organic light-emitting functional layer facing away from the substrate. The above buffer structure may effectively improve heat dissipation and shielding performances of the display apparatus, and the buffer structure is of a single-layer structure, which is conducive to reducing a thickness of the display apparatus and achieving a thin and light display apparatus.

In some embodiments, as shown in FIG. 7, the above display apparatus further includes a cover plate 7. The cover plate 7 is located on a light-emitting side of the display panel 6. The display panel includes a display region 61, a bonding region 62 located on a side of the display region facing away from the light-emitting side thereof, and a bending region 63 connecting the display region 61 and the bonding region 62. The buffer structure is located between the display region 61 and the bonding region 62. The buffer structure may play a good buffering role on the back side of the display panel. The buffer structure may be directly attached to the back side of the display region of the display panel. The buffer structure may play a better role in heat conduction. Heat of the display panel 6 may be conducted to the buffer structure for heat dissipation, and heat dissipation of the display apparatus may be improved.

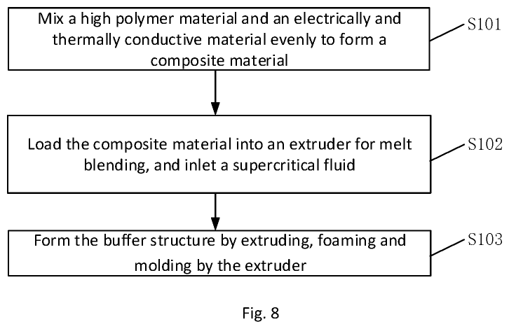

Based on the same inventive concept, referring to FIG. 1, and as shown in FIG. 8, embodiments further provide a preparation method for a buffer structure. The preparation method is applicable to the buffer structure provided by the above embodiments. The preparation method includes following steps.

First, according to step S101, a high polymer material and electrically and thermally conductive material are mixed evenly to form a mixture, and the mixture forms a composite material. In some embodiments, the high polymer material and the electrically and thermally conductive material may be mixed at a certain ratio. Further, a composition of the composite material may further include copper powder, and the high polymer material, the electrically and thermally conductive material and the copper powder are evenly mixed to form the composite material.

Second, according to step S102, the composite material is loaded into an extruder for melt blending, and a supercritical fluid is inlet to the extruder, so that the composite material forms a composite foaming material. In some embodiments, the extruder may be a twin screw extruder and the supercritical fluid may be high pressure carbon dioxide or high pressure nitrogen.

Then, according to step S103, the buffer structure is formed by extruding the composite foaming material from the extruder for foaming molding.

Based on the above preparation method, it should be noted that, in the preparation process, during melt blending of the mixture in the extruder, the mixture needs to be heated at a preset temperature. In this process, the needed temperature is high, and in order to ensure the performance of the electrically and thermally conductive material, the above preparation method is applicable to the preparation of a buffer structure using a high-temperature-resistant electrically and thermally conductive material. Therefore, the preparation method is applicable to the preparation of a buffer structure with one or more of carbon fiber, carbon nanotube and graphene, as the electrically and thermally conductive material. In the extruder, the material of the substrate layer is in a molten state while the electrically and thermally conductive material does not melt, and the materials are stirred and mixed uniformly in the extruder, and then extruded and foamed into shape. The preparation process is simple and reliable and has a production efficiency, which is convenient for industrialized production and is conducive to saving the cost of preparation and lowering the cost of production.

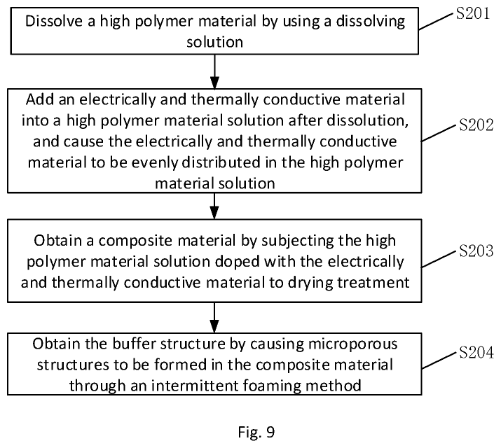

Based on the same inventive concept, referring to FIG. 1, and as shown in FIG. 9, embodiments further provide another preparation method for a buffer structure. The preparation method is applicable to the buffer structure provided by the above embodiments. The preparation method includes the following steps.

First, according to step S201, a dissolving solution is used to dissolve a high polymer material. In some embodiments, the dissolving solution may be dimethylformamide.

Second, according to step S202, an electrically and thermally conductive material is added into a high polymer material solution after dissolving, and the electrically and thermally conductive material is caused to be evenly distributed in the high polymer material solution by stirring. In addition, copper powder may further be added to the high polymer material solution, so as to further improve a shielding capacity of the buffer structure prepared.

Third, according to step S203, the high polymer material solution doped with the electrically and thermally conductive material is subjected to drying treatment so as to obtain a composite material.

Finally, according to step S204, microporous structures are caused to be formed in the composite material through an intermittent foaming method, so as to obtain the buffer structure.

The preparation method uses the dissolving solution to dissolve the high polymer material to mix the electrically and thermally conductive material and high polymer material. The temperature will not be excessively high in the preparation process. The preparation process is applicable to some electrically and thermally conductive materials that are not resistant to high temperatures. In some embodiments, the preparation method is applicable to electrically and thermally conductive materials including titanium carbide. The preparation process is relatively simple and reliable, and a good buffer structure may be formed.

Obviously, those of skill in the art may make various modifications and variations of the embodiments of the present disclosure without departing from the spirit and scope of the present disclosure. Thus, if these modifications and variations of the present disclosure fall within the scope of the present disclosure claims and their technical equivalents, the present disclosure is intended to encompass these modifications and variations as well.

1. A buffer structure, comprising:
a substrate layer, wherein a plurality of microporous structures are distributed in the substrate layer, the substrate layer is doped with an electrically and thermally conductive material, the electrically and thermally conductive material is distributed in a whole-layer structure of the substrate layer, and the electrically and thermally conductive material forms a heat conduction network structure in the substrate layer.

2. The buffer structure according to claim 1, wherein the electrically and thermally conductive material comprises at least one of carbon fiber, carbon nanotubes, graphene, and titanium carbide.

3. The buffer structure according to claim 1, wherein the substrate layer comprises a high polymer material.

4. The buffer structure according to claim 3, wherein the high polymer material comprises at least one of polypropylene, polyethylene terephthalate, thermoplastic polyurethane, polyvinylidene fluoride, and polylactic acid.

5. The buffer structure according to claim 3, wherein a weight ratio of the high polymer material to the electrically and thermally conductive material is (90-95):(5-10).

6. The buffer structure according to claim 3, wherein the substrate layer is further doped with copper powder.

7. The buffer structure according to claim 6, wherein a weight ratio of the high polymer material to the copper powder to the electrically and thermally conductive material is (85-90):(5-3):(10-7).

8. The buffer structure according to claim 1, wherein a diameter of the microporous structure is larger than or equal to 1 μm and is smaller than or equal to 10 μm.

9. The buffer structure according to claim 1, wherein a layer thickness of the substrate layer is larger than or equal to 0.1 mm and is smaller than or equal to 0.5 mm.

10. The buffer structure according to claim 1, wherein a copper foil is arranged on a surface of the substrate layer.

11. The buffer structure according to claim 1, wherein reticulated tape is arranged on outmost sides of two sides of the buffer structure respectively.

12. A display apparatus, comprising a display panel and the buffer structure according to claim 1, wherein the buffer structure is located on a back side of the display panel.

13. A preparation method for a buffer structure, comprising:
mixing a high polymer material and an electrically and thermally conductive material evenly to form a composite material;
loading the composite material into an extruder for melt blending, and inletting a supercritical fluid; and
forming the buffer structure by extruding, foaming, and molding by the extruder.

14. A preparation method for a buffer structure, comprising:
dissolving a high polymer material by using a dissolving solution;
adding an electrically and thermally conductive material into a high polymer material solution after dissolution, and causing the electrically and thermally conductive material to be evenly distributed in the high polymer material solution;
obtaining a composite material by subjecting the high polymer material solution doped with the electrically and thermally conductive material to drying treatment; and
obtaining the buffer structure by causing microporous structures to be formed in the composite material through an intermittent foaming method.
